(19) United States
(12) Patent Application Publication
(10) Pub. No.: US 2006/0212555 A1
(43) Pub. Date: Sep. 21, 2006

(54) Network analyzing method and a network analyzing apparatus

(75) Inventor: Koji Harada, Kobe-Shi (JP)

Correspondence Address: OHLANDT, GREELEY, RUGGIERO & PERLE, LLP, ONE LANDMARK SQUARE, 10TH FLOOR, STAMFORD, CT, 06901, US

(73) Assignee: Agilent Technologies, Inc., Palo Alto, CA (US)

(21) Appl. No.: 10/553,276

(22) PCT Filed: Jun. 3, 2004
(86) PCT No.: PCT/US04/17461

§ 371 Date: Oct. 13, 2005

(30) Foreign Application Priority Data
Jun. 3, 2003 (JP) 2003-158091

(51) Int. Cl. G06F 15/173; G01R 23/00

(52) U.S. Cl. 709/223; 324/76.19

(57) ABSTRACT

A network analyzing apparatus (100) and method for analyzing the network properties of a device under test (20) to which modulated signals are applied including modulating data contained in output signals (10) of the device under test (20), generating modulated signals (140) based on demodulated data and setting data supplied in advance, outputting the modulated signals as reference signals, and analyzing (150) the network properties of the device under test (20) by comparing or referencing the output signals of the device under test and these reference signals.

### BACKGROUND OF THE INVENTION

1. Field of the Invention

The present invention pertains to a method and an apparatus for analyzing the network properties of a device under test and in particular, relates to a method and an apparatus with which the network properties of a device under test can be analyzed without applying reference signals to the device under test.

2. Discussion of the Background Art

A network analyzer (for instance, refer to JP (Kokai) 10[1998]-142,273 (Page 2, FIG. 3)) is an example of a device that analyzes the network properties of a device under test.

Conventional network analyzers comprise a reference signal source, a receiver, and multiple measurement ports. The reference signal source is a sine-wave signal source selectively connected to a measurement port. Sine-wave signals output by a reference signal source generally sweep frequency or electric power. The receiver receives input signals and output signals at the measurement port. The device under test is connected to a measurement port. Conventional network analyzers constructed in this way analyze the network properties of a device under test by applying sine-wave signals, which are reference signals, to a device under test while frequency sweeping or electric power sweeping and measuring the signals reflected from the measurements of the device under test or the signals transmitted by the device under test (for instance, JP (Kokai) 10[1998]-142,273 (Page 2, FIG. 3)).

A spectrum analyzer or signal measurement device is a device having a structure and functions similar to those of a network analyzer. These devices differ from a network analyzer that analyzes the properties of a device under test in that they are devices that analyze the properties of the very same signals that are input (for instance, JP (Kokai) 2[1990]-259,579 (Page 2, FIG. 8) and JP (Kokai) 2000-324,026 (Page 3, FIG. 1)).

As is clear from the above-mentioned description, by means of a conventional network analyzer, reference signals are applied to a device under test in order to analyze the network properties of the device under test. However, there are cases in which network properties cannot be analyzed because it is difficult or impossible to apply these reference signals to the device under test. The wireless transmitter of a wireless base station of a portable telephone is an example of this type of device under test. Wireless transmitters modulate carrier signals based on data received from a radio transmission path and amplify the modulated carrier signals with an electric amplifier and transmit these signals from an antenna. For instance, it is necessary to isolate this electric amplifier and apply reference signals to the input part of the electric amplifier in order to measure the network properties of the electric amplifier. Moreover, it is necessary to detect the input part of the electric amplifier and connect signal lines for input of reference signals to the input part of the electric amplifier in order to measure the network properties of the electric amplifier. These operations are very troublesome to those performing the test and both are causes of mis-measurement. In extreme cases there is a chance that the device under test will be damaged. Furthermore, there are cases in which it is necessary to operate the device under test under conditions that are different than normally used in order to analyze the network properties of a device under test with a conventional network analyzer, making it impossible to analyze network properties under actual operating conditions. The case where swept sine-wave signals, which are reference signals output by the network analyzer, are applied to an amplifier for modulated signals and the sine-wave signals are amplified by this amplifier is an example of analysis under conditions that are different from those normally used.

In light of the above-mentioned circumstances, the present invention is to provides an apparatus and a method with which the network properties of a device under test can be analyzed without applying reference signals to the device under test. Additional, the present invention provides a network analyzing apparatus and network analyzing method with which signal generation for application to the device under test is not necessary. The present invention also provides an apparatus and a method with which the network properties of a device under test are analyzed under actual operating conditions.

### SUMMARY OF THE INVENTION

The present invention is a network analyzing apparatus that is adapted to the generation of modulated signals applied to a device under test and the analysis of network properties of the device under test from the modulated signals output from the device under test and the modulated signals that are generated, making it possible to analyze the network properties of the device under test without applying reference signals to the device under test. As a result, there is no damage to the device under test as a result of network analysis and the complexity of the operation during network analysis of a device under test is eliminated. Moreover, the generation of signals for application to the device under test is unnecessary. In addition, the network properties of the device under test can be analyzed under actual operating conditions. Thus, the dynamic properties of the device under test reflected by the temperature of the device under test and so forth under operating conditions can be measured. The present invention is also adapted to the analysis of network properties of a device under test by a network analyzing apparatus without applying reference signals to the device under test, and therefore, amplitude noise and phase noise of the modulated signals can be measured.

The present invention operates in such a way that modulated signals applied to a device under test are generated and the network properties of the device under test are analyzed from the modulated signals output from the device under test and the modulated signals that are generated.

Moreover, the apparatus of the present invention is an apparatus with which the network properties of a device under test to which modulated signals are applied are analyzed; it comprises a demodulation means, a reference-signal generation means, and an analysis means; this demodulation means demodulates the data contained in the output signals of this device under test; this reference-signal generation means generates the above-mentioned modulated signals based on the data demodulated by this demodulation means and setting data supplied in advance and outputs these modulated signals as reference signals; and this analysis means analyzes the network properties of the device under test by comparing or referencing the output signals of this device under test and these reference signals.

The method of the present invention is a method whereby the network properties of a device under test to which modulated signals are applied are analyzed; and it comprises the step wherein the data contained in the output signals of this device under test are demodulated, the step wherein the above-mentioned modulated signals are generated based on the above-mentioned modulated data and setting data supplied in advance and these modulated signals are output as reference signals; and the step wherein the network properties of the device under test are analyzed by comparing or referencing the output signals of the above-mentioned device under test and the above-mentioned reference signals.

Furthermore, by means of the above-mentioned apparatus and method of the present invention, the above-mentioned modulated signals are digital modulated signals and the above-mentioned data are digital data.

A network analyzing device which analyzes network properties of a device under test to which modulated signals are applied, the device comprising a demodulator which demodulates data contained in output signals from the device under test; a reference-signal generator which generates the modulated signals based on data that has been demodulated by the demodulator and setting data supplied in advance and outputs the modulated signals as reference signals; and an analyzer which analyzes the network properties of the device under test by comparing or referencing the output signals of the device under test and the reference signals.

The analyzer analyzes the frequency properties of the device under test by: modeling the device under test with a filter; fixing the pulse response of the filter from the output signals of the device under test and the reference signals; and performing a Fourier transform of the pulse response.

Alternatively, the analyzer analyzes the electrical power properties of the device under test by: detecting the amplitude ratio of the output signals of the device under test and the reference signals; and analyzing the correlation between the amplitude of the output signals of the device under test and the amplitude ratio.

The analyzer may also analyze the electrical power properties of the device under test by: detecting the phase difference between the output signals of the device under test and the reference signals; and analyzing the correlation between the amplitude of the output signals of the device under test and the phase difference.

Furthermore, the analyzer analyzes the amplitude noise properties of the device under test by: detecting the amplitude difference between the output signals of the device under test and the reference signals; and performing a Fourier transform of the amplitude difference.

Still yet the analyzer may analyze the phase noise properties of the device under test by detecting the phase difference between the output signals of the device under test and the reference signals; and performing a Fourier transform of the phase difference.

Preferably, modulated signals are digital modulated signals, and the data is digital data.

A network analyzing method for analyzing network properties of a device under test to which modulated signals are applied, the method comprising modulating data contained in output signals of the device under test to produce demodulated data; generating modulated signals based on the demodulated data and predetermined setting data; outputting the modulated signals as reference signals; and analyzing the network properties of the device under test by comparing or referencing the output signals of the device under test and the reference signals.

### BRIEF DESCRIPTION OF THE DRAWINGS

FIG. 1 is a drawing showing the structure of the network analyzing apparatus according to the present intention;

FIG. 2 is a flow chart showing the operation of the network analyzing apparatus;

FIG. 3 is a drawing showing the structure of the analyzer when the frequency properties of the device under test are analyzed;

FIG. 4 is a drawing showing the structure of the system identification device;

FIG. 5 is a flow chart showing the procedure for the analysis of the frequency properties of the device under test;

FIG. 6 is a drawing showing the structure of the system identification device according to another embodiment;

FIG. 7 is a flow chart showing the procedure for analyzing the frequency properties of the device under test according to another embodiment;

FIG. 8 is a drawing showing the structure of the analyzer when the electrical power-electrical power ratio properties of the device under test are analyzed;

FIG. 9 is a flow chart showing the structure of the analyzer when the electrical power-electrical power ratio properties of the device under test are analyzed;

FIG. 10 is a drawing showing the structure of the analyzer when the electrical power-phase properties of the device under test are analyzed;

FIG. 11 is a flow chart showing the procedure for analyzing the electric power-phase properties of the device under test;

FIG. 12 is a drawing showing the structure of analyzer when the amplitude noise properties of the device under test are analyzed;

FIG. 13 is a flow chart showing the procedure for analyzing the amplitude noise properties of the device under test;

FIG. 14 is a drawing showing the structure of analyzer when the phase noise properties of the device under test are analyzed;

FIG. 15 is a flow chart showing the procedure for analyzing the phase noise properties of the device under test;

FIG. 16 is a drawing showing the structure of the network analyzing apparatus according to yet another embodiment of the present invention; and

FIG. 17 is a drawing showing the structure of the network analyzing apparatus according to still yet another embodiment of the present invention.

### DETAILED DESCRIPTION OF THE PREFERRED EMBODIMENT

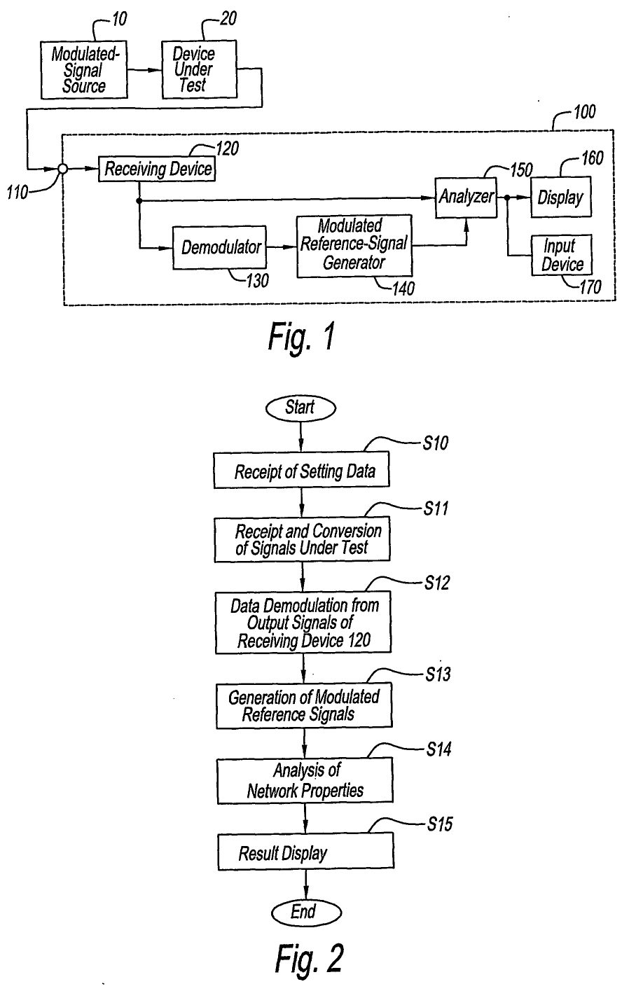

The present invention will be described based on preferred embodiments shown in the attached drawings. The first embodiment of the present invention is a network analyzing apparatus with which the network properties of the device under test are analyzed by the method of the present invention, and the structure thereof is shown in FIG. 1.

FIG. 1 shows a network analyzing apparatus 100, which is an embodiment of the present invention, as well as a modulated signal source 10 and a device under test (DUT) 20.

Modulated signal source 10 is a signal source that generates modulated signals that have been modulated based on certain data. The data in the present embodiment are preferably digital data. However, the form of the data is not limited to digital data. The data can be analog signals such as, for example, sine-wave signals. The data for modulation are generated by modulated signal source 10, pre-housed in modulated signal source 10, or are input from outside of modulated signal source 10.

Device under test 20 outputs signals in response to the output signals of modulated signal source 10. The output signals of device under test 20 are signals under test.

Network analyzing apparatus 100 comprises an input terminal 110, a receiving device 120, a demodulator 130 that is an example of the demodulation means, a modulated reference-signal generator 140 that is an example of a reference-signal generation means, an analyzer 150 that is an example of an analysis means, a display 160, and an input device 170.

Input terminal 110 is a terminal for receiving signals. In FIG. 1, input terminal 110 is connected to the output terminal of device under test 20 and receives signals under test.

Receiving device 120 receives signals under test through input terminal 110 and converts the signals under test so that they are suitable for demodulator 130 and analyzer 150. For instance, receiving device 120 adjusts the level and filters and/or converts the signals under test from analog to digital and introduces the signals to demodulator 130 and analyzer 150. In the simplest case, receiving device 120 introduces the received signals under test to demodulator 130 and analyzer 150 without performing any conversion treatment of the received signals under test. Moreover, receiving device 120 preferably has the input impedance needed to receive the signals under test.

Demodulator part 130 demodulates the data contained in the output signals of receiving device 120. When the signals under test are modulated analog signals, the analog signals are demodulated. Moreover, when the signals under test are modulated digital signals, the digital data are demodulated.

Modulated reference-signal generator 140 generates modulated signals based on the data demodulated by demodulator 130. The modulated signals that are generated become the reference signals for the network property analysis of device under test 20.

Analyzer 150 analyzes the network properties of device under test 20 from the output signals of receiving device 120 and the output signals of modulated reference-signal generator 140, and outputs the analysis results to display 160. Moreover, analyzer 150 controls receiving device 120, demodulator 130, and modulated reference-signal generator 140 for analysis. Analyzer 150 comprises an operation means, such as a microprocessor or a digital signal processor. Various analysis functions are performed depending on the program that is executed by the analyzer. Analyzer 150 comprises a means (e.g., an A/D converter) for sampling signals and converting them to digital data (not illustrated) when the output signals of receiving device 120 and modulated reference-signal generator 140 are analog signals.

Display 160 displays the measurement results of network analyzing apparatus 100 and various data, including setting data. For instance, display 160 is an LED lamp or liquid crystal panel display. Display 160 should preferably be capable of displaying various data. Display 160 can be a printer and/or other output device.

Input device 170 receives data input from the user of network analyzing apparatus 100. For instance, input device 170 comprises an input means suitable for the input of data, such as a button, vernier knob, or keyboard. Input device 170 should preferably be a means for inputting a variety of data such as, for example, a floptical disk or LAN interface.

Operation of network analyzing apparatus 100 will now be described. A flowchart representing an exemplary operating procedure of network analyzing apparatus 100 is shown in FIG. 2. The flowchart shown in FIG. 2 represents a main operating procedure of network analyzing apparatus 100 when the network properties of device under test 20 are analyzed.

In step S10, the setting data necessary for the analysis of network properties of device under test 20 are received through input device 170. The setting data may include, for instance, demodulation parameters for demodulator 130 and modulated reference-signal generator 140. It is possible to bypass step and proceed to step S11 if, for example, the data that have already been set can be reused.

In step S11, receiving device 120 converts the signals under test received through input terminal 110 so that they can be used by demodulator 130 and analyzer 150. For instance, receiving device 120 adjusts the level and filters, and/or converts the signals under test from analog to digital. In the simplest of cases, receiving device 120 introduces the received signals under test, as is, to demodulator 130 and analyzer 150.

In step S12, demodulation part 130 demodulates the data contained in the output signals of receiving device 120. When the signals under test are modulated analog signals, analog signals are demodulated. Moreover, when the signals under test are modulated digital signals, digital data are demodulated. The parameters needed for demodulation are given to demodulator 130 from analyzer 150, preferably at the time of demodulation. The parameters provided include, for example, the symbol rate, modulation formats, and so forth when digital modulation signals are demodulated. The modulation formats are, for example, QPSK, 16QAM, FSK, and etc.

In step S13, modulated reference-signal generator 140 generates modulated signals based on data that have been demodulated by demodulator 130 and supplies the signals to analyzer 150. When modulated signals are generated, the parameters necessary for generation of modulated signals are provided from analyzer 150 to modulated reference-signal generator 140. The parameters provided include, for example, the symbol rate, the modulation format, and the transmission speed when, for instance, modulated digital signals are generated. Moreover, filter parameters include filter type and order. The type of filter is preferably a Nyquist filter or Butterworth filter. The modulation format is as follows.

Next, in step S14, analyzer 150 analyzes the network properties of device under test 20 by comparing or referencing the output signals of receiving device 120 and the output signals of modulated reference-signal generator 140. That is, the network properties of the device under test are analyzed by comparing or referencing two modulated signals. The order of analysis of the network properties in this step is described in detail in paragraphs given below.

In step S15, display 160 displays, in an appropriate display form, the network properties of device under test 20 analyzed by analyzer 150.

Network analyzing apparatus 100 constructed and operated as described above is capable of analyzing the network properties of device under test 20 without applying reference signals to device under test 20.

The network property and analysis procedure in step S14 will now be described in detail. The analysis of network properties in step S14 is different from conventional analysis. One difference is that the signals that are used for conventional network property analysis are single-frequency signals, but the method of the present invention uses modulated signals. For instance, the frequency sweep and electrical power sweep in conventional network property analysis have a constant sweep direction regardless of whether it is a continuous sweep or an intermittent sweep. However, the output signals of receiving device 120 and the output signals of modulated reference-signal generator 140 are modulated signals in the network analyzing apparatus 100 constructed as described above and therefore, the direction in which the frequency and electrical power thereof change is irregular and not constant. Consequently, a conventional analysis method cannot be used.

The procedure whereby the frequency properties of device under test 20 are analyzed, the procedure whereby the electric power properties of device under test 20 are analyzed, the procedure whereby the amplitude noise properties of device under test 20 are analyzed, and the procedure whereby the phase noise properties of device under test 20 are analyzed are described in order below.

The procedure whereby the frequency properties of device under test 20 are analyzed will now be described first. The frequency properties of device under test 20 are analyzed by modeling the device under test with a filter and identifying the pulse response of the filter.

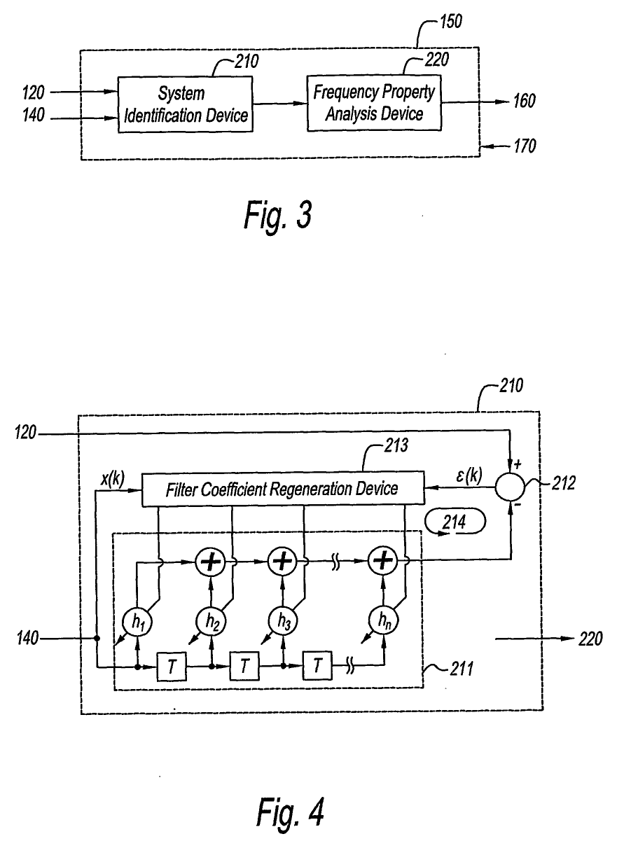

Several functional elements are provided inside analyzer 150 when the frequency properties of device under test 20 are analyzed. An exemplary internal structure of analyzer 150 is shown in FIG. 3 because it facilitates the description of this analysis procedure. Analyzer 150 comprises a system identification device 210 and a frequency property analysis device 220. System identification device 210 is a functional element that models device under test 20 with a filter and identifies the pulse response of the filter. Frequency property analysis device 220 is a functional element that analyzes the frequency properties of the device under test from the pulse response that has been identified by system identification device 210

The internal block diagram of system identification device 210 is shown in FIG. 4. System identification device 210 comprises an FIR filter 211, a comparator part 212, and a filter coefficient regeneration device 213. FIR filter 211 is an n-order transversal-type FIR filter representing device under test 20. FIR filter 211 comprises n number of adders, n number of delayers, and (n+1) number of variable filter coefficients h₀ through hₙ. The delay time of one delayer is preferably the sampling interval T of the input data.

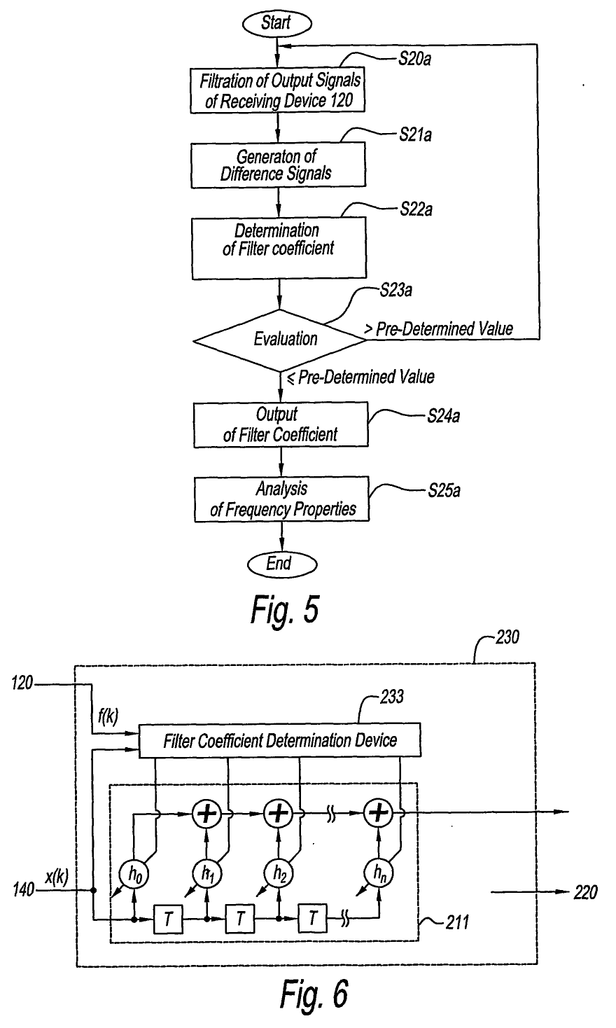

FIG. 5 is a flow chart showing an exemplary procedure for the frequency property analysis of device under test 20 in analyzer 150 in which functional elements are provided as described above.

In step S20a, filter 211 filters the output signals of receiving device 120.

In step S21a, comparator 212 compares the output signals of modulated reference-signal generator 140 and the output signals of filter 211 and generates difference signals. The difference signals are obtained by subtracting the output signals of filter 211 from the output signals of modulated reference-signal generator 140. Difference signals should be generated and therefore, the output signals of modulated reference-signal generator 140 can also be subtracted from the output signals of filter 211.

In step S22a, filter coefficient regenerator 213 regenerates filter coefficients h₀ through hₙ of FIR filter 211 while referencing the output signals of the modulated reference-signal generator 140 and the output signals of comparator 212. New filter coefficients h₀ through hₙ set by calculation using formula 1.

$$h ( k + 1 ) = h ( k ) - μ ∇ e ( k ) \\ However , h ( k ) = [ \begin{matrix}{h}_{0} ( k ) & {h}_{1} ( k ) & ⋯ & {h}_{n - 1} ( k ) & {h}_{n} ( k )\end{matrix} ] \\ e ( k ) = E [ {ɛ}^{2} ( k ) ] \\ \begin{matrix}∇ e ( k ) = [ \begin{matrix}\frac{\partial e ( k )}{\partial {h}_{0} ( k )} & \frac{\partial e ( k )}{\partial {h}_{1} ( k )} & ⋯ & \frac{\partial e ( k )}{\partial {h}_{n - 1} ( k )} & \frac{\partial e ( k )}{\partial {h}_{n} ( k )}\end{matrix} ] \\ = {[ \begin{matrix}- 2 E [ ɛ ( k ) x ( k ) ] \\ - 2 E [ ɛ ( k ) x ( k - 1 ) ] \\ ⋮ \\ - 2 E [ ɛ ( k ) x ( k - n + 1 ) ] \\ - 2 E [ ɛ ( k ) x ( k - n ) ]\end{matrix} ]}^{T}\end{matrix} \qquad ( formula 1 )$$

Here, h(k) is the matrix representing filter coefficients h₀ through hₙ at time k indicating the present time. h(k+1) is the matrix representing newly set filter coefficients h₀ through hₙ. ε(k) is the output signal of comparator 212 at time k. x(k) is the matrix representing the output signal of modulated reference-signal generator 140 at time k. E [ ] is the expectation operand. μ is any value.

In step S23a, the output signals of comparator 212 and a pre-determined value are compared and evaluated. Processing proceeds to step S24a when the output signals of comparison part 212 are the pre-determined value or smaller. If the output signals of comparison part 212 are greater than the pre-determined value, the processing in step S22a and step S23a is again performed. Re-execution of this processing is represented as loop 214 in FIG. 4.

In step S24a, system identification part 210 outputs filter coefficients h₀ through hₙ of FIR filter 211 to frequency property analyzer 220. Filter coefficients h₀ through hₙ and FIR filter 211 are also the pulse response of device under test 20.

In step S25a, frequency property analyzer 220 performs Fourier transform of filter coefficients h₀ through hₙ of FIR filter 211 to obtain the frequency-amplitude properties or frequency-phase properties of device under test 20. These properties can also be obtained simultaneously.

New filter coefficients h₀ through hₙ should be calculated from the current filter coefficients h₀ through hₙ in accordance with changes over time in the output signals of device under test 20 (i.e., changes over time in the output signals of receiving device 120). Therefore, for instance, formula 2 can also be used in place of formula 1.
h(k+1)=h(k)+2ε(k)x(k) (formula 2)

Moreover, system identification device 210 can be replaced by system identification device 230 shown in FIG. 6. System identification device 230 is characterized in that at times, such as when there are no changes over time in the filter coefficient to be identified, the optimum filter coefficient can be easily identified when compared to system identification device 210. System identification device 230 in FIG. 6 comprises a filter 211 and a filter coefficient determination device 233. FIR Filter 211 is an n-order transversal FIR filter representing device under test 20. FIR filter 211 comprises n number of adders, n number of delayers, and (n+1) number of variable filter coefficients h₀ through hₙ. The delay time of one delayer is the sampling interval T of the input data.

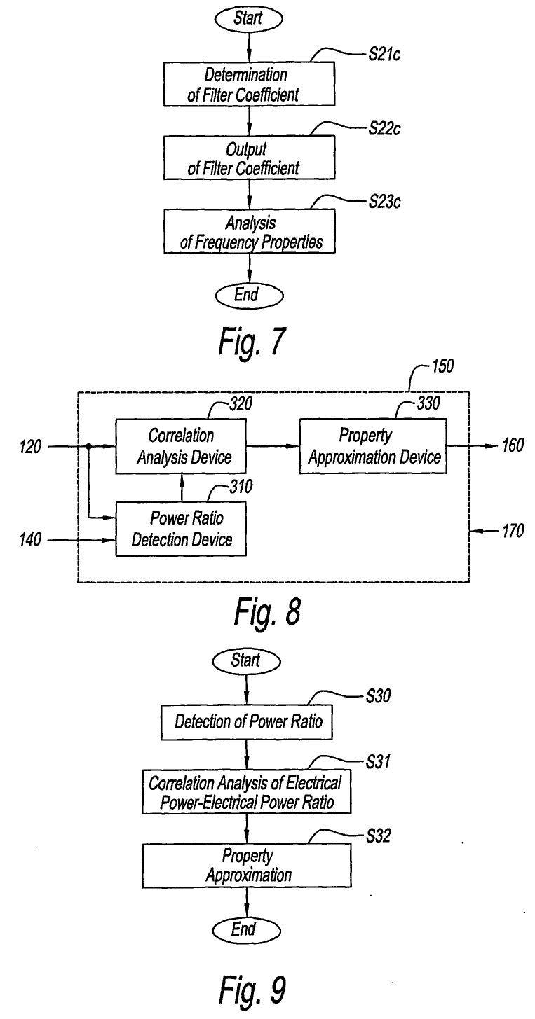

FIG. 7 shows an exemplary flow chart representing the procedure for the frequency property analysis of device under test 20 in analyzer 150 in which functional elements are provided as described above.

First, in step S21c, filter coefficient determination device 233 identifies filter coefficients h₀ through hₙ of filter 211 from formula 3 by referencing the output signals of receiving device 120 and the output signals of modulated reference-signal generator 140.
h=R⁻¹·b (formula 3)

Here, h is a matrix representing filter coefficients h₀ through hₙ. R⁻¹ is the reverse matrix of the auto-correlation matrix R of x(n). B is the mutual correlation matrix between x(n) and f(n). x(k) is the matrix representing the output signals of modulated reference-signal generator 140 at time k. f(k) is the matrix representing the output signals of receiving device 120 at time k. Moreover, auto-correlation matrix R and mutual correlation matrix b are as follows.

$$h = [ \begin{matrix}{h}_{0} \\ {h}_{1} \\ ⋮ \\ {h}_{n}\end{matrix} ]$$

$$R = [ \begin{matrix}R ( 0 ) & R ( 1 ) & ⋯ & R ( n ) \\ R ( 1 ) & R ( 0 ) & ⋯ & R ( n - 1 ) \\ ⋮ & ⋮ & ⋰ & ⋮ \\ R ( n ) & R ( n - 1 ) & ⋯ & R ( 0 )\end{matrix} ]$$

$$R ( s - t ) = E [ x ( k - s ) x ( k - t ) ]$$

$$b = [ \begin{matrix}b ( 0 ) \\ b ( 1 ) \\ ⋮ \\ b ( n )\end{matrix} ]$$

$$b ( s ) = E [ f ( k ) x ( k - s ) ]$$

Here, E [ ] is the expectation operand.

In step S22c, system identification part 210 outputs the filter coefficients h₀ through hₙ of FIR filter 211 to frequency property analyzer 220. Filter coefficients h₀ through hₙ of FIR filter 211 are also the pulse response of device under test 20.

In step S23c, frequency property analyzer 220 performs Fourier transform of filter coefficients h₀ through hₙ of FIR filter 211 to obtain the frequency-amplitude properties or frequency-based properties of device under test 20. These properties can be obtained simultaneously.

System identification device 210 and system identification device 310 can comprise an IIR filter in place of FIR filter 211, as yet another modified example.

The procedure for analyzing the electrical power properties of device under test 20 will be described. The electrical power properties of device under test 20 are the electrical power-amplitude properties and the electrical power-phase properties. The procedure for analyzing the electrical power-amplitude properties will now be described.

Several functional elements are provided inside analyzer 150 when the electrical power-amplitude properties of device under test 20 are analyzed. The internal structure of analyzer 150 is shown in FIG. 8. Analyzer 150 comprises an electrical power ratio detection device 310, a correlation analysis device 320, and a property approximation device 330.

FIG. 9 shows an exemplary flow chart representing a procedure for the electrical power-amplitude property analysis of device under test 20 in analyzer 150 in which functional elements are provided as described above.

In step S30, electrical power ratio detection device 310 calculates the ratio of the magnitude of the instantaneous electrical power amplitude of the output signals of modulated reference-signal generation device 140 to the magnitude of the instantaneous electrical power amplitude of the output signals of receiving device 120 and outputs this ratio to correlation analyzer 320.

In step S31, correlation analysis device 320 analyzes the correlation between the magnitude of the electrical power of the output signals of receiving device 120 and the electrical power ratio calculated by electrical power ratio detection part 310. For instance, it draws a scatter diagram of the magnitude of the electrical power of the output signals of receiving device 120 and the electrical power ratio calculated by electrical power ratio detection device 310.

In step S32, property approximation device 330 approximates the correlation property analyzed by correlation analysis device 320. First, the groups of points plotted on the scatter diagram made by correlation analyzer 320 are fitted to a curve. The modulated signals are irregular in terms of the direction in which electrical power changes and therefore, there are cases in which the points are biased on the scatter diagram. For instance, there are cases in which there are no points in certain regions and cases in which there are many points where the magnitude of the amplitude of the output signals of receiving device 120 is the same but the electrical power ratio is different. An approximation curve is drawn on the scatter diagram in this step so as to clarify the electrical power properties of device under test 20, which are represented as non-uniform or random points.

The procedure for analyzing the electrical power-phase properties of device under test 20 will now be described.

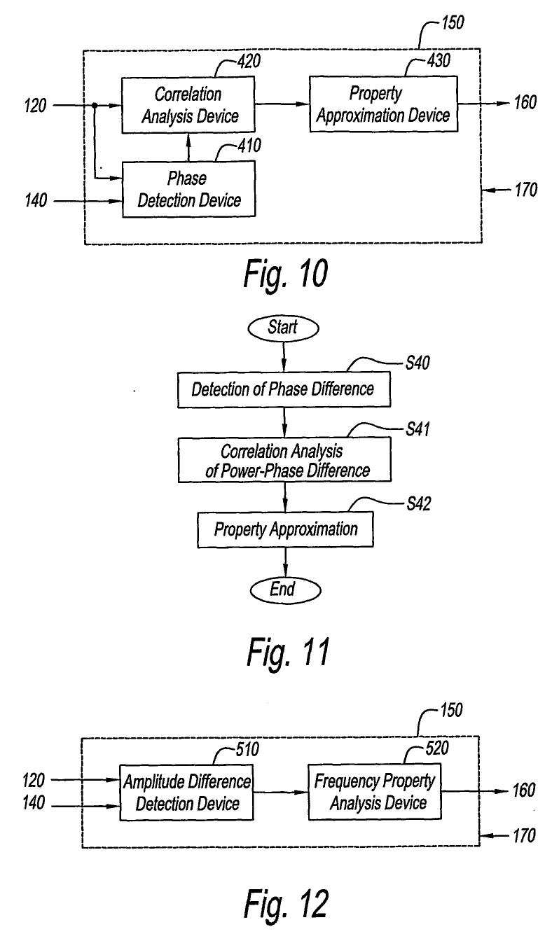

Several functional elements are provided inside analyzer 150 when the electrical power-phase properties of device under test 20 are analyzed. The internal structure of analyzer 150 is shown in FIG. 10. Analyzer 150 comprises a phase difference detection device 410, a correlation analysis device 420, and a property approximation device 430.

FIG. 11 shows an exemplary flow chart representing a procedure for the electrical power-phase property analysis of device under test 20 in analyzer 150 in which functional elements are provided as described above.

In step S40, phase difference detection device 410 detects the difference between the output signals of receiving device 120 and the output signals of modulated reference-signal generation part 140 and outputs this difference to correlation analysis device 420. The phase difference is found by calculation as the phase difference between the instantaneous vector of the output signals of receiving device 120 and the instantaneous vector of the output signals of modulated reference-signal generation device 140. For instance, the phase difference φ is found by the following formula.

$$ϕ = {cos}^{- 1} \frac{{M}_{a}^{2} + {M}_{b}^{2} - {M}_{c}^{2}}{2 {M}_{a} {M}_{b}}$$

Here, Mₐ is the magnitude of the instantaneous vector of the output signals of receiving device 120, M_{b} is the magnitude of the instantaneous vector of the output signals of modulated reference-signal generation device 140, and M_{c} is the magnitude of the instantaneous vector of the difference signal between the output signals of receiving device 120 and the output signals of modulated reference-signal generation device 140.

In step S41, correlation analysis device 420 analyzes the correlation property between the magnitude of the electric power of the output signals of receiving device 120 and the phase difference calculated by phase difference detection device 410. For instance, it plots a scatter diagram of the magnitude of the electric power of the output signals of receiving device 120 and the phase difference calculated by electric power ratio detection device 310.

In step S42, property approximation device 430 approximates the correlation property analyzed by correlation analysis device 420. The groups of points plotted on the scatter diagram made by correlation analysis device 420 are fitted to a curve. The modulated signals are irregular in terms of the direction in which electrical power changes and therefore, there are cases in which the points are biased on the scatter diagram. For instance, there are cases in which there are no points in certain regions and cases in which there are many points where the magnitude of the amplitude of the output signals of receiving device 120 is the same but the electrical power ratio is different. An approximation curve is drawn on the scatter diagram in this step so as to clarify the electrical power properties of device under test 20, which are represented as non-uniform or random points.

The procedure for analyzing the amplitude noise properties of device under test 20 will now be described.

Several functional elements are provided inside analyzer 150 when the amplitude noise properties of device under test 20 are analyzed. The internal structure of analyzer 150 is shown in FIG. 12. Analyzer 150 comprises an amplitude difference detection part 510 and a frequency property analysis device 520.

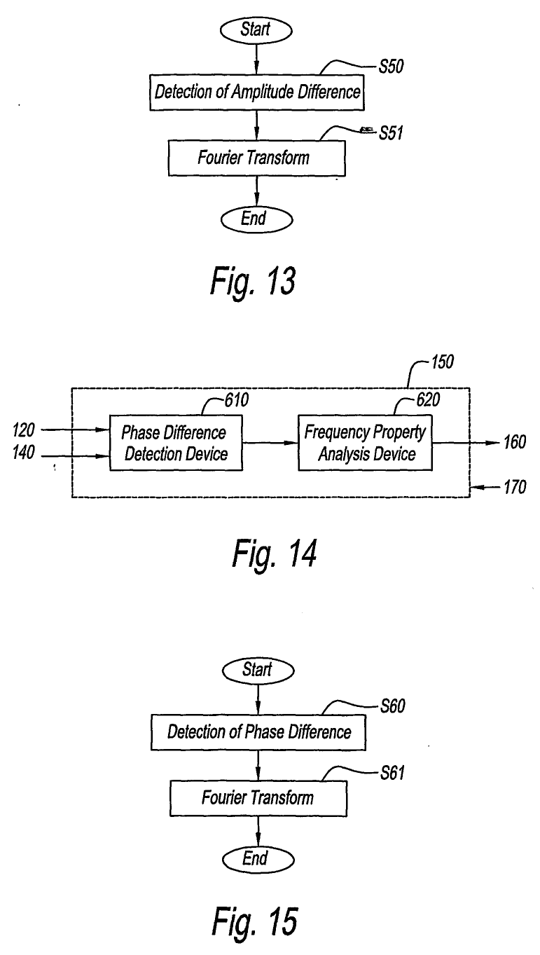

FIG. 13 shows an exemplary flow chart representing a procedure for the electrical power-amplitude property analysis of device under test 20 in analyzer 150 in which functional elements are provided as described above.

In step S50, amplitude difference detection part 510 detects the difference between the magnitude of the instantaneous electrical power amplitude of the output signals of receiving device 120 and the magnitude of the instantaneous output signals of modulated reference-signal generation device 140. The amplitude difference detected by this step is output to frequency property analysis device 520 as amplitude difference signals that change over time.

In step S51, frequency property analysis device 520 performs a Fourier transform of amplitude difference signals output from amplitude difference detection device 510. The spectrum of the amplitude difference signals represents the amplitude noise density property in the carrier waves of the output signals of device under test 20, which are modulated signals.

The procedure for analyzing the phase noise properties of device under test 20 will now be described.

Several functional elements are provided inside analyzer 150 when the phase noise properties of device under test 20 are analyzed. The internal structure of analyzer 150 is shown in FIG. 14. In FIG. 14, analyzer 150 comprises a phase difference detection device 610 and a frequency property analysis device 620.

FIG. 15 shows an exemplary flow chart representing a procedure for the phase noise property analysis of device under test 20 in analyzer 150 in which functional elements are provided as described above.

In step S60, phase difference detection device 610 detects the phase difference between the output signals of receiving device 120 and the output signals of modulated reference-signal generation device 140 and outputs this difference to correlation analysis device 420. The phase difference is found by calculation as the phase difference between the instantaneous vector of the output signals of receiving device 120 and the instantaneous vector of the output signals of modulated reference-signal generation device 140. For instance, the phase difference φ is found by the following formula.
b(s)=E[f(k)x(k−s)]

Here, Mₐ is the magnitude of the instantaneous vector of the output signals of receiving device 120, M_{b} is the magnitude of the instantaneous vector of the output signals of modulated reference-signal generation device 140, and M_{c} is the magnitude of the instantaneous vector of the difference signal between the output signals of receiving device 120 and the output signals of modulated reference-signal generation device 140.

The phase difference detected by this step is output to frequency property analysis device 620 as phase difference signals that change over time.

In step S61, frequency property analysis device 620 performs a Fourier transform of the phase difference detected by phase detection device 610. The spectrum of the phase distance signals represents the phase noise density properties in the carrier waves of the output signals of device under test 20, which are modulated signals.

Several variations of network analyzing apparatus 100 shown in FIG. 1 are possible. For instance, network analyzing apparatus 100 does not necessarily comprise one device with all functions, but can also comprise two devices.

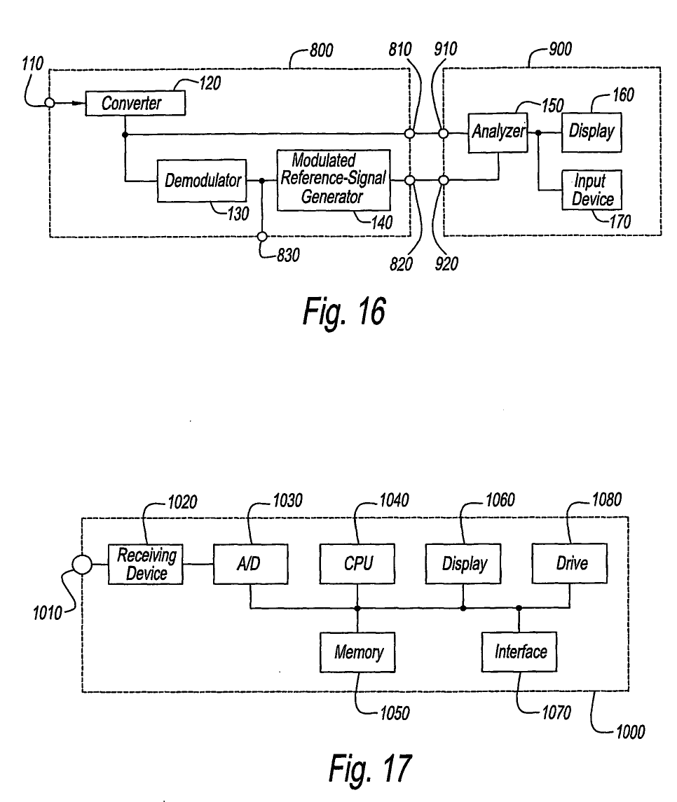

Therefore, network analyzing apparatus 700 comprising two devices will be described as a second embodiment of the present invention. FIG. 16 is a structural diagram of network analyzing apparatus 700. Network analyzing apparatus 700 is network analyzing apparatus 100 divided into two devices. The same reference symbols are used for structural elements in FIG. 1 and FIG. 16 having the same function and properties. Network analyzing apparatus 700 comprises a first device 800 and a second device 900. First device 800 in turn comprises an input terminal 110, a receiving device 120, a demodulation device 130, a modulated reference-signal generation part 140, a measured-signal output terminal 810, and a reference-signal output terminal 820. Measured-signal output terminal 810 is a terminal with which the output signals of receiving device 120 are output to outside the device. Reference-signal output terminal 820 is the terminal with which the output signals of modulated reference-signal generation device 140 are output to outside the device. Moreover, first device 800 has a modulated-signal input terminal 830. Modulated-signal input terminal 830 is a terminal that is adapted to being capable of inputting from the outside the data necessary from modulation at modulated reference-signal generation part 140. Second device 900 comprises a measured-signal input terminal 910, a reference-signal input terminal 920, an analyzer 150, a display 160, and an input device 170. Measured-signal input terminal 910 is the terminal that receives the modulated signals under test and supplies these to analyzer 150. Reference-signal output terminal 820 is the terminal that receives the modulated reference signals and feeds these to analyzer 150. By means of network analyzing apparatus 700, demodulating part 130 and modulated reference-signal generation part 140 are separate from analyzer 150 and therefore, it is easy to respond to wireless standards that quickly become outdated by a new generation. Moreover, analyzing apparatus 700 has modulated-signal input terminal 830 and therefore, analog signals and digital data that are used to generate modulated signals can be received by signal source 10. When the analog signals and digital data that are used by signal source 10 to generate modulated signals are known, the signal source that generates the known analog signals and digital data can be connected to modulated-signal input terminal 830 of network analyzing apparatus 700.

Moreover, the network analyzing apparatus can have the smallest analog circuit necessary so that all other functions are performed by execution of programs with a computer. Therefore, network analyzing apparatus 1000 will be described as a third embodiment of the present invention. A structural diagram of network analyzing apparatus 1000 is shown in FIG. 17. Network analyzing apparatus 1000 comprises an input terminal 1010, a receiving device 1020, an analog-digital converter 1030, a CPU 1040, a memory 1050, a display 1060, an interface 1070, and a drive 1080. Input terminal 1010 is a terminal for receiving signals. This terminal is connected to the output terminal of device under test 20 and receives signals under test. Receiving device 1020 massages or prepares signals under test so that they can be used for conversion by analog-digital converter 1030. Analog-digital converter 1030 samples the output signals of receiving device 1020. CPU 140 controls the various structural elements inside the device and performs various operations by execution of programs. The programs performed by CPU 1040 are preferably housed in memory 1050, the storage medium of drive 1080, or are received through an interface. Memory 1050 and drive 1080 are devices that store the various data, such as sampling data and measurement results of signals under test, and programs. Interface 1070 enables communication between network analyzing apparatus 1000 and outside devices. If the programs that perform some or all of each of the structural elements of network analyzing apparatus 100, or the programs that realize some or all of the procedure in FIG. 2, are performed by CPU 1040, network analyzing apparatus 1000 constructed in this way becomes the equivalent of network analyzing apparatus 100. This type of substitution is similarly possible with network analyzing apparatus 700.

Furthermore, all functions of the network analyzing apparatus can be preformed with hardware. For instance, analyzer 150 in the first embodiment can be fully constructed from hardware such as an FPGA rather than an operating means that executes programs.

1. A network analyzing device which analyzes network properties of a device under test to which modulated signals are applied, said device comprising:
a demodulator which demodulates data contained in output signals from said device under test;
a reference-signal generator which generates said modulated signals based on data that has been demodulated by said demodulator and outputs said modulated signals as reference signals; and
an analyzer which analyzes said network properties of said device under test by comparing or referencing the output signals of said device under test and said reference signals.

2. The apparatus according to claim 1, wherein said analyzer analyzes the frequency properties of said device under test by: modeling said device under test with a filter; fixing the pulse response of said filter from said output signals of said device under test and said reference signals; and performing a Fourier transform of said pulse response.

3. The apparatus according to claim 1, wherein said analyzer analyzes the electrical power properties of said device under test by: detecting the amplitude ratio of said output signals of said device under test and said reference signals; and analyzing the correlation between the amplitude of said output signals of said device under test and said amplitude ratio.

4. The apparatus according to claim 1, wherein said analyzer analyzes the electrical power properties of said device under test by: detecting the phase difference between said output signals of said device under test and said reference signals; and analyzing the correlation between the amplitude of said output signals of said device under test and said phase difference.

5. The apparatus according to claim 1, wherein said analyzer analyzes the amplitude noise properties of said device under test by: detecting the amplitude difference between said output signals of said device under test and said reference signals; and performing a Fourier transform of said amplitude difference.

6. The apparatus according to claim 1, wherein said analyzer analyzes the phase noise properties of said device under test by detecting the phase difference between said output signals of said device under test and said reference signals; and performing a Fourier transform of said phase difference.

7. The apparatus according to claim 1, wherein said modulated signals are digital modulated signals, and said data is digital data.

8. A network analyzing method for analyzing network properties of a device under test to which modulated signals are applied, said method comprising:
modulating data contained in output signals of said device under test to produce demodulated data;
generating modulated signals based on said demodulated data;
outputting said modulated signals as reference signals; and
analyzing said network properties of said device under test by comparing or referencing said output signals of said device under test and said reference signals.

9. The method according to claim 8, wherein said network properties analyzed are the frequency properties of said device under test and wherein said analyzing comprises: modeling said device under test with a filter; fixing the pulse response of said filter from the output signals of said device under test and said reference signals; and performing a Fourier transform of said pulse response.

10. The method according to claim 8, wherein said network properties analyzed are the electrical properties of said device under test and wherein said analyzing comprises: detecting the amplitude ratio of said output signals of said device under test and said reference signals; and analyzing the correlation between the amplitude of said output signals of said device under test and said amplitude ratio.

11. The method according to claim 8, wherein said network properties analyzed are the electrical properties of said device under test and wherein said analyzing comprises: detecting the phase difference between said output signals of said device under test and said reference signals; and analyzing the correlation between the amplitude of the output signals of said device under test and said phase difference.

12. The method according to claim 8, wherein said network properties analyzed are the amplitude noise properties of said device under test and wherein said analyzing comprises: detecting the amplitude difference between said output signals of said device under test and said reference signals; and performing a Fourier transform of said amplitude difference.

13. The method according to claim 8, wherein said network properties analyzed are the phase noise properties of said device under test and wherein said analyzing comprises: detecting the phase difference between said output signals of said device under test and said reference signals; and performing a Fourier transform of said phase difference.

14. The method according to claim 8, wherein said modulated signals are digital modulated signals, and said data are digital data.
